(19) United States
(12) Patent Application Publication
(10) Pub. No.: US 2006/0121659 A1
(43) Pub. Date: Jun. 8, 2006

(54) FABRICATING METHOD OF THIN FILM TRANSISTOR AND POLY-SILICON LAYER

(76) Inventor: Hsi-Ming Chang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/905,930

(22) Filed: Jan. 27, 2005

(30) Foreign Application Priority Data
Dec. 3, 2004 (TW) 93137333

(51) Int. Cl. H01L 21/8234

(52) U.S. Cl. 438/197

(57) ABSTRACT

A manufacturing method of a thin film transistor is provided. An amorphous silicon layer (a-Si layer) is formed on a substrate. A nitrogen-plasma is formed to form a silicon nitride layer on the a-Si layer, wherein the step of forming the silicone nitride layer and the step of forming the a-Si layer are in-situ. Next, the a-Si layer is transformed to a poly-silicon layer. The poly-silicon layer is patterned to form a poly-silicon island. Afterward a gate insulation layer is formed on the substrate covering the poly-silicon island. A gate is formed on the gate insulation layer above the poly-silicon island. A source/drain is formed in the poly-silicon island beside of the gate.

### CROSS-REFERENCE TO RELATED APPLICATION

This application claims the priority benefit of Taiwan application serial no. 93137333, filed Dec. 3, 2004.

### BACKGROUND OF THE INVENTION

1. Field of Invention

The present invention relates to fabrication of thin film transistor (TFT) and polysilicon. More particularly, the present invention relates to a method for fabricating a low-temperature polysilicon TFT and a low-temperature polysilicon layer.

2. Description of Related Art

In the early technology of fabricating the polysilicon TFT, it uses the process of solid phase crystallization (SPC) in fabrication. Since the process temperature is as high as 1000 degrees, it necessary to use the quartz substrate with high melting point. In addition, since the quartz substrate has much higher cost than that of the glass substrate and the substrate size is limited, it can only be used in past day for developing a small panel, such as 2 to 3 inches. Recently, as the continuous development of the laser technology, the excimer laser annealing (ELA) process has been applied to the fabrication of polysilicon TFT.

The excimer laser annealing process uses the laser beam to illuminate on the amorphous silicon (a-Si) layer, so that the a-Si layer is melted and then is re-crystallized to form the polysilicon layer. Since the fabrication process for the polysilicon TFT uses the excimer laser annealing process, the fabrication process can be performed under a temperature of 600 degrees. As a result, the polysilicon TFT formed by this process is also called the low-temperature polysilicon TFT (LTPS TFT).

Generally, after forming the amorphous silicon layer and before performing annealing process on the amorphous silicon layer, the surface of the amorphous silicon layer usually has native oxide being formed. Since this native oxide usually include the impurities, such as carbon, nitrogen, oxygen, or sodium ions, in non-uniform distribution, the native oxide would affect the quality of the polysilicon layer being subsequently formed, and the device characteristics. Currently, the usual treatment is using HF acid to remove the native oxide on the surface of the amorphous silicon layer. It should be noted that the HF acid by itself is a highly dangerous chemical material, but also after removing the native oxide layer, an additional cleaning process of HF is performed, so as to remove the HF acid on the surface of the amorphous silicon layer and an additional surface treatment process of a-Si layer is performed to prevent the native oxide with impurities form being formed again. This method increases the complexity of the fabrication process.

### SUMMARY OF THE INVENTION

For an objective, the invention provides a method for fabricating a TFT with a simplified fabrication process.

In addition, for another objective, the invention further provides a method for fabricating a polysilicon layer, so as to reduce the issues of poor quality on the polysilicon layer due to contamination from the native oxide on the surface of the amorphous silicon layer.

The invention provides a method for fabricating a TFT. First, an amorphous silicon layer is formed on a substrate. Then, a nitrogen plasma is formed, so as to form a silicon nitride layer on the amorphous silicon layer, wherein the formation of the amorphous silicon layer and the formation of the silicon nitride layer use in-situ process. Then, the amorphous silicon layer is transformed into a polysilicon layer. The polysilicon layer is patterned, to form a polysilicon island. Then, a gate insulating layer is formed over the substrate and covers the polysilicon island. A gate electrode is formed on the gate insulating layer, wherein the gate electrode is located above the polysilicon island. A source/drain electrode is formed in the polysilicon island at each side of the gate electrode.

According to a preferred embodiment of the invention, the foregoing silicon nitride layer has a thickness of, for example, 5-15 Angstroms.

According to a preferred embodiment of the invention, the flowing rate of nitrogen in the nitrogen plasma is, for example, 5-15 slm (standard litre per minute).

According to a preferred embodiment of the invention, the method to transform the foregoing amorphous silicon layer into polysilicon layer is, for example, performing a laser annealing process on the amorphous silicon. In addition, the laser annealing process can be, for example, an excimer laser annealing process.

According to a preferred embodiment of the invention, before forming the amorphous silicon layer over the substrate, the foregoing method for fabrication TFT further includes forming a buffer layer over the substrate.

According to a preferred embodiment of the invention, after forming the source/drain electrode, the method for fabrication TFT further includes forming a patterned dielectric layer over the substrate, wherein the patterned dielectric layer covers the gate electrode and exposes a portion of the source/drain electrode. Then, a source/drain conductive layer is formed on the patterned dielectric layer, and the source/drain conductive layer is electrically coupled to the source/drain electrode.

The invention provides method for fabricating polysilicon layer, including forming an amorphous silicon layer over a substrate. Then, a nitrogen plasma is formed, so as to form a silicon nitride layer on the amorphous silicon layer. Wherein, the formation of the amorphous silicon layer and the silicon nitride layer includes an in-situ process. And then, the amorphous silicon layer is transformed into a polysilicon layer.

According to a preferred embodiment of the invention, the foregoing silicon nitride layer has a thickness of, for example, 5-15 Angstroms.

According to a preferred embodiment of the invention, the flowing rate of nitrogen in the nitrogen plasma is, for example, 5-15 slm.

According to a preferred embodiment of the invention, method to transform the foregoing amorphous silicon layer into polysilicon layer is, for example, performing a laser annealing process on the amorphous silicon. In addition, the laser annealing process can be, for example, an excimer laser annealing process.

According to a preferred embodiment of the invention, before forming the amorphous silicon layer over the substrate, the foregoing method for fabrication polysilicon further includes forming a buffer layer over the substrate.

In the foregoing embodiments, the methods for fabrication TFT or polysilicon are using the nitrogen plasma to form a silicon nitride layer on the amorphous silicon layer after the amorphous silicon layer is formed. Wherein, the formation of the amorphous silicon layer and the silicon nitride layer includes an in-situ process, so that the invention can effectively solve the contamination of native oxide on the surface of the amorphous silicon layer without increasing the fabrication complexity.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1B are drawings, schematically illustrating the fabricating method for the polysilicon layer, according to a preferred embodiment of the invention.

FIGS. 2A-2C are drawings, schematically illustrating the fabricating method for the TFT, according to a preferred embodiment of the invention.

### DESCRIPTION OF THE PREFERRED EMBODIMENTS

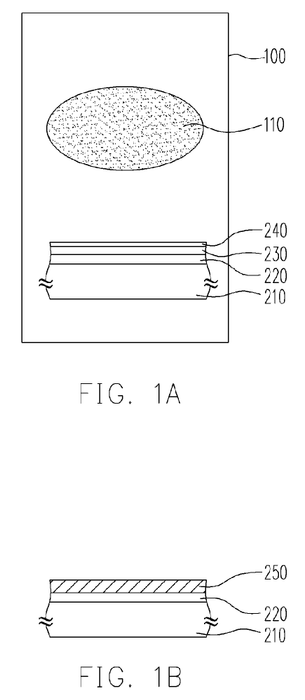

FIGS. 1A-1B are drawings, schematically illustrating the fabricating method for the polysilicon layer, according to a preferred embodiment of the invention. In FIG. 1A, the method for fabricating a polysilicon layer includes the following steps. First, an amorphous silicon layer 230 is formed over a substrate 210, wherein the amorphous silicon layer 230 is formed by, for example, plasma enhanced chemical vapor deposition process (PECVD). Then, a nitrogen plasma 110 is formed, so as to form a silicon nitride layer 240 on the amorphous silicon layer 230. Wherein, the formation of the amorphous silicon layer 230 and the silicon nitride layer 240 includes an in-situ process. In other words, the amorphous silicon layer 230 and the silicon nitride layer 240 are formed in the same reaction chamber 100. Then, the amorphous silicon layer 230 is transformed into a polysilicon layer 250, as shown in FIG. 1B. The method for transforming the amorphous silicon layer 230 into the polysilicon layer 250 includes, for example, performing a laser annealing process on the amorphous silicon layer 230, so as to transform the amorphous silicon layer 230 into the polysilicon layer 250.

In the preferred embodiment, the flow rate of nitrogen gas in the nitrogen plasma 110 is, for example, 5-15 slm, that is, the nitrogen gas with the flowing rate is fed into the reaction chamber 100. In addition, the thickness of the silicon nitride layer 240 is, for example, 5-15 Angstroms. In the invention, after the amorphous silicon layer 230 is formed, then the silicon nitride layer 240 is formed at the same reaction chamber 100, so that almost no native oxide is formed on the amorphous silicon layer 230. This results in better quality for the polysilicon layer 250, which is subsequently formed. In comparing with the conventional technology about using HF acid to remove the native oxide, the invention can reduce the fabrication steps. Furthermore, the issue about the HF residue on the amorphous silicon layer 230 can be almost eliminated.

Referring to FIG. 1B, in another embodiment, before forming the amorphous silicon layer 230, it further includes forming a buffer layer 220, and then the amorphous silicon layer 230 is formed over the buffer layer. In addition, the method for forming the buffer layer 220 is, for example, silicon oxide formed by low pressure chemical vapor deposition (LPCVD) or PECVD. Further in more detail, the buffer layer 220 is, for example, a single-layer of silicon oxide, or dual-layer of silicon oxide and silicon nitride. The thickness of the buffer layer 220 is, for example, about 300 nm. It should be noted that the proper thickness of the buffer layer 220 not only can prevent the metal ions in the substrate 210 from being diffused into the amorphous silicon layer 230, but also can reduce the cooling rate of the polysilicon layer 250, so as to form a larger silicon grain.

The foregoing laser annealing process includes, for example, excimer laser annealing process, and the laser used in the excimer laser annealing process is, for example, the XeCl laser, ArF laser, KrF laser, or XeF laser. It should be noted that the laser annealing process is not limited to the excimer laser. It can also use the solid-state laser. The solid-state laser includes, for example, Nd:YAG (Yttrium Aluminum Garnet) laser, Nd:YVO₄ (Yttrium Ortho Vanadate) laser, or diode pumped solid state laser (DPSS). In addition, the substrate 210 is, for example, the glass substrate, quartz substrate, or plastic substrate. The method for forming the TFT by using the polysilicon layer 250 is described as follows.

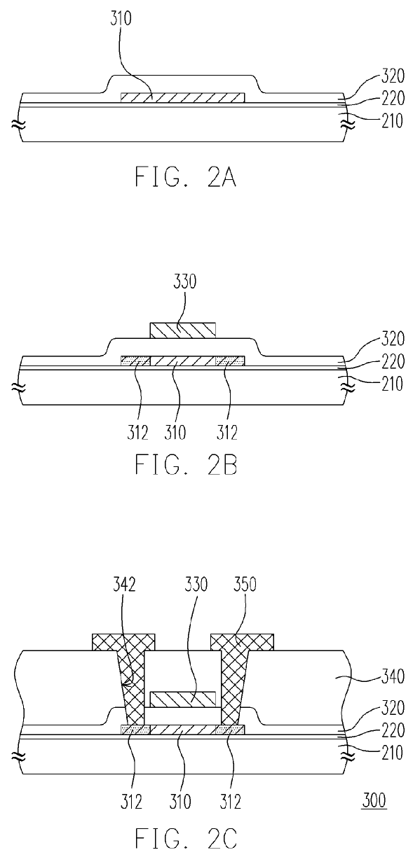

FIGS. 2A-2B are drawings, schematically illustrating the fabricating method for the TFT, according to a preferred embodiment of the invention. In FIG. 2A, after completion of the polysilicon layer 250, the polysilicon layer 250 is patterned to form a polysilicon island 310. The method for patterning the polysilicon layer 250 includes, for example, photolithographic process and etching process.

Then, a gate insulating layer 320 is formed over the substrate 210, and covers over the polysilicon island 310. In addition, the gate insulating layer 320 includes, for example, silicon oxide, silicon nitride or other insulating material. In more detail, the formation of the silicon oxide is, for example, PECVD process, and the reaction gas is SiH₄/N₂O or TEOS/O₂. Moreover, the formation of the silicon nitride is, for example, PECVD process, and the reaction gas is SiH₄/NH₃. Particularly, after the gate insulating layer 320 is formed, a channel doping process can be performed on the polysilicon island 310, so as to adjust the electric properties of the polysilicon island 310.

In FIG. 2B, a gate electrode 330 is formed on the gate insulating layer 320, wherein the gate electrode 330 is located above the polysilicon island 310. In more detail, the formation of the gate electrode 330 includes, for example, forming a gate electrode material layer over the gate insulating layer 320 by sputtering process. The material is, for example, Cr or other metallic material. Then, the gate electrode material layer is performed with photolithographic process and the etching process, so as to form the gate electrode 330.

After completion of the gate electrode 330, the gate electrode 330 is used as the mask to perform an ion doping process, so as to form a source/drain electrode 312 in the polysilicon island 310 at each side of the gate electrode 330. It should be noted that in order to further solve the hot carrier effect, it can also perform a lightly doped drain doping (LDD) process, so as to form a lightly doped source/drain region (not shown) between the source/drain electrode 312. Particularly, after completion of the ion doping process, it can also include an ion activation process on the doped structure. The ion activation process includes, for example, excimer laser annealing (ELA), rapid thermal annealing (RTA), furnace annealing (FA), or self-activation.

In FIG. 2C, then, a patterned dielectric layer 340 is formed over the substrate 210, and the patterned dielectric layer 340 is covering over the gate electrode 330 but exposing a portion of the source/drain electrode 312. In further more detail, the formation of the patterned dielectric layer 340 includes, for example, first forming a dielectric layer over the substrate 210 by PECVD. The material for dielectric layer includes, for example, silicon oxide, silicon nitride, or other insulating material. Then, the photolithographic process and etching process are performed to form multiple openings 342 in the dielectric layer, so as to form the patterned dielectric layer 340. Wherein, the openings 342 expose a portion of the source/drain electrode 312.

Then, a source/drain electrode conductive layer 350 is formed over the dielectric layer 340 and fills into the opening 342, so that the source/drain electrode conductive layer 350 is electrically coupled with the source/drain electrode 312. Up to here, the TFT 300 is basically accomplished. In addition, the material of the source/drain conductive layer 350 includes, for example, metal or other conductive material.

In summary, for comparing with the conventional technology, the invention uses the nitrogen plasma treatment on the amorphous silicon layer to form a silicon nitride layer, so as to solve the issue about the contamination caused by the native oxide on the surface of the amorphous silicon layer. The TFT or polysilicon layer formed by the invention can have better quality.

In addition, since the amorphous silicon layer and the silicon nitride layer are the in-situ process, the fabrication method for the TFT and polysilicon has the advantages of in-time without adding extra fabrication equipment.

In addition, since the formation of the silicon nitride layer on the amorphous silicon layer, it can reduce the native oxide on the surface of the amorphous silicon layer, but also does not need to use the HF acid for removing the native oxide on the surface of the amorphous silicon layer. Therefore, the method for fabricating TFT and polysilicon layer of the invention can save the cost, and can prevent the dangerous HF acid from being used.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for fabricating a thin film transistor (TFT), comprising:
forming an amorphous silicon layer over a substrate;
forming a nitrogen plasma, to form a silicon nitride layer on a surface of the amorphous silicon layer, wherein an in-situ process is used for forming the amorphous silicon layer and the silicon nitride layer;
transforming the amorphous silicon layer into a polysilicon layer;
patterning the polysilicon layer, to form a polysilicon island;
forming a gate insulating layer over the substrate, covering over the polysilicon island;
forming a gate electrode on the gate insulating layer, wherein the gate electrode is located above the polysilicon island; and
forming a source/drain electrode in the polysilicon island at each side of the gate electrode.

2. The method of claim 1, wherein a thickness of the silicon nitride layer is 5-15 Angstroms.

3. The method of claim 1, wherein a flowing rate of applying the nitrogen plasma is 5-15 slm.

4. The method of claim 1, wherein the step of transforming the amorphous silicon layer into the polysilicon layer comprises performing a laser annealing process on the amorphous silicon layer.

5. The method of claim 4, wherein the laser annealing process includes an excimer annealing laser annealing process.

6. The method of claim 1, before forming the amorphous silicon layer over the substrate, further comprising forming a buffer layer over the substrate.

7. The method of claim 1, after the source/drain electrode, further comprising forming a patterned dielectric layer over the substrate, wherein the patterned dielectric layer covers over the gate electrode, and exposes a portion of the source/drain electrode.

8. The method of claim 7, after forming the patterned dielectric layer, further comprising forming a source/drain conductive layer over the patterned dielectric layer, wherein the source/drain conductive layer is electrically coupled with the source/drain electrode.

9. A method for fabricating a polysilicon layer, comprising:
forming an amorphous silicon layer over a substrate;
forming a nitrogen plasma, to form a silicon nitride layer on a surface of the amorphous silicon layer, wherein an in-situ process is used for forming the amorphous silicon layer and the silicon nitride layer; and
transforming the amorphous silicon layer into a polysilicon layer.

10. The method of claim 9, wherein a thickness of the silicon nitride layer is 5-15 Angstroms.

11. The method of claim 9, wherein a flowing rate of applying the nitrogen plasma is 5-15 slm.

12. The method of claim 9, wherein the step of transforming the amorphous silicon layer into the polysilicon layer comprises performing a laser annealing process on the amorphous silicon layer.

13. The method of claim 12, wherein the laser annealing process includes an excimer annealing laser annealing process.

14. The method of claim 9, before forming the amorphous silicon layer over the substrate, further comprising forming a buffer layer over the substrate.
